(19) United States
(12) Patent Application Publication
(10) Pub. No.: US 2024/0186342 A1
(43) Pub. Date: Jun. 6, 2024

(54) IMAGE SENSING DEVICE

(71) Applicant: SK hynix Inc., Icheon-si (KR)

(72) Inventor: Sung Wook CHO, Icheon-si (KR)

(21) Appl. No.: 18/355,238

(22) Filed: Jul. 19, 2023

(30) Foreign Application Priority Data
Dec. 2, 2022 (KR) 10-2022-0166967

(51) Int. Cl. H01L 27/146

(52) U.S. Cl. CPC H01L 27/14605; H01L 27/14621; H01L 27/14623; H01L 27/14627; H01L 27/1463; H01L 27/14645; H04N 25/78

(57) ABSTRACT

An image sensing device includes a pixel region provided in a first portion of a semiconductor substrate such that photoelectric conversion elements for converting incident light into an electrical signal are disposed in the first portion of the semiconductor substrate, a dummy region located outside the pixel region to surround the pixel region and provided in a second portion of the semiconductor substrate without including a photoelectric conversion element, first microlenses disposed over the first portion of the semiconductor substrate and in the pixel region, the first microlenses configured to converge the incident light onto corresponding photoelectric conversion elements, second microlenses disposed over the second portion of the semiconductor substrate and in the dummy region, the second microlenses isolated from the first microlenses, and at least one alignment pattern disposed in the second portion of semiconductor substrate so as to be aligned with the second microlenses.

### CROSS-REFERENCE TO RELATED APPLICATION

This patent document claims the priority and benefits of Korean patent application No. 10-2022-0166967, filed on Dec. 2, 2022, which is incorporated by reference in its entirety as part of the disclosure of this patent document.

### TECHNICAL FIELD

The technology and implementations disclosed in this patent document generally relate to an image sensing device.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as digital cameras, camcorders, personal communication systems (PCSs), game consoles, surveillance cameras, medical micro-cameras, robots, etc.

The image sensing device may be roughly divided into CCD (Charge Coupled Device) image sensing devices and CMOS (Complementary Metal Oxide Semiconductor) image sensing devices. Recently, analog and digital control circuits for use in the CMOS image sensing devices can be integrated into a single integrated chip (IC), so that the CMOS image sensing devices are being widely used for many applications.

### SUMMARY

Various embodiments of the disclosed technology relate to an image sensing device capable of easily performing overlay analysis using a deep trench isolation (DTI) structure.

In accordance with an embodiment of the disclosed technology, an image sensing device may include a pixel region provided in a portion of a semiconductor substrate such that photoelectric conversion elements for converting incident light into an electrical signal are disposed in the first portion of the semiconductor substrate, a dummy region located outside the pixel region to surround the pixel region and provided in a second portion of the semiconductor substrate without including a photoelectric conversion element, first microlenses disposed over the first portion of the semiconductor substrate and in the pixel region, the first microlenses configured to converge the incident light onto corresponding photoelectric conversion elements, second microlenses disposed over the second portion of the semiconductor substrate and in the dummy region, the second microlenses isolated from the first microlenses, and at least one alignment pattern disposed in the second portion of the semiconductor substrate so as to be aligned with the second microlenses.

In accordance with another embodiment of the disclosed technology, an image sensing device may include a first region configured to include photoelectric conversion elements for converting incident light into electrical signals and first microlenses for converging incident light onto the photoelectric conversion elements, and a second region located outside the first region and configured to include second microlenses having a size different from a size of the first microlenses, wherein the second region includes at least one alignment pattern disposed in a semiconductor substrate so as to be aligned with a portion of the second microlenses.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a view illustrating an example of an approximate planar structure of a light receiving region shown in FIG. 1 based on some implementations of the disclosed technology.

FIG. 3 is a view exemplarily illustrating how one microlens is formed to cover four unit pixels in a light receiving region shown in FIG. 1 based on some implementations of the disclosed technology.

FIG. 4 is an enlarged view exemplarily illustrating a portion of an edge region denoted by a dotted line in the light receiving region shown in FIG. 2 based on some implementations of the disclosed technology.

FIG. 5 is a cross-sectional view illustrating an example of the light receiving region taken along the line X1-X1′ shown in FIG. 4 based on some implementations of the disclosed technology.

FIG. 6 is a cross-sectional view illustrating an example of the light receiving region taken along the line X2-X2′ shown in FIG. 4 based on some implementations of the disclosed technology.

FIG. 7 is a cross-sectional view illustrating an example of the light receiving region taken along the line X1-X1′ shown in FIG. 4 based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device capable of easily performing overlay analysis using a deep trench isolation (DTI) structure. The disclosed technology provides various implementations of the image sensing device capable of easily performing overlay analysis using the deep trench isolation (DTI) structure.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

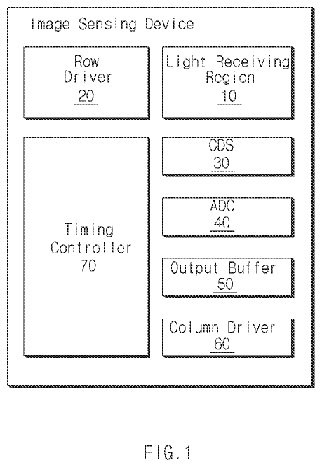

FIG. 1 is a block diagram illustrating an image sensing device based on some implementations of the disclosed technology.

Referring to FIG. 1, the image sensing device may include a light receiving region 10, a row driver 20, a correlated double sampler (CDS) 30, an analog-to-digital converter (ADC) 40, an output buffer 50, a column driver 60, and a timing controller 70.

The light receiving region 10 may include a plurality of unit pixels consecutively arranged in a row direction and a column direction. Each unit pixel may photoelectrically convert incident light received from the outside to generate an electrical signal (i.e., a pixel signal) corresponding to the incident light. The pixel signal may be read out by the pixel transistors and used for image generation.

The light receiving region 10 may include a plurality of microlenses arranged over the color filters to converge incident light upon a corresponding color filter. The microlenses may be formed in a structure in which one microlens covers four adjacent unit pixels. For example, light incident through one microlens may be divided into four channels by a deep trench isolation (DTI) structure serving as a pixel isolation structure (i.e., a device isolation structure), and the resultant four light rays may be incident upon photoelectric conversion regions of the corresponding pixels. Alternatively, microlenses may be formed one by one for each unit pixel. A lens capping layer may be disposed over the microlenses to protect microlenses while preventing the flare phenomenon caused by the microlenses. The lens capping layer may include a low temperature oxide (LTO) film.

Unit pixels of the light receiving region 10 may receive driving signals (for example, a row selection signal, a reset signal, a transmission (or transfer) signal, etc.) from the row driver 20. Upon receiving the driving signal, the unit pixels may be activated to perform the operations corresponding to the row selection signal, the reset signal, and the transfer signal.

The row driver 20 may activate the light receiving region 10 to perform certain operations on the unit pixels in the corresponding row based on control signals provided by controller circuitry such as the timing controller 70. In some implementations, the row driver 20 may select one or more pixel groups arranged in one or more rows of the light receiving region 10. The row driver 20 may generate a row selection signal to select one or more rows from among the plurality of rows. The row driver 20 may sequentially enable the reset signal and the transfer signal for the unit pixels arranged in the selected row. The pixel signals generated by the unit pixels arranged in the selected row may be output to the correlated double sampler (CDS) 30.

The correlated double sampler (CDS) 30 may remove undesired offset values of the unit pixels using correlated double sampling. In some implementations, upon receiving a clock signal from the timing controller 70, the CDS 30 may sequentially sample and hold voltage levels of the reference signal and the pixel signal, which are provided to each of a plurality of column lines from the light receiving region 10. That is, the CDS 30 may sample and hold the voltage levels of the reference signal and the pixel signal which correspond to each of the columns of the light receiving region 10. In some implementations, the CDS 30 may transfer the reference signal and the pixel signal of each of the columns as a correlate double sampling (CDS) signal to the ADC 40 based on control signals from the timing controller 70.

The ADC 40 is used to convert analog CDS signals received from the CDS 30 into digital signals. The analog-to-digital converter (ADC) 40 may compare a ramp signal received from the timing controller 70 with the CDS signal received from the CDS 30, and may thus output a comparison signal indicating the result of comparison between the ramp signal and the CDS signal. The analog-to-digital converter (ADC) 40 may count a level transition time of the comparison signal in response to the ramp signal received from the timing controller 70, and may output a count value indicating the counted level transition time to the output buffer 50.

The output buffer 50 may temporarily store column-based image data provided from the ADC 40 based on control signals of the timing controller 70. The image data received from the ADC 40 may be temporarily stored in the output buffer 50 based on control signals of the timing controller 70. The output buffer 50 may provide an interface to compensate for data rate differences or transmission rate differences between the image sensing device and other devices.

The column driver 60 may select a column of the output buffer 50 upon receiving a control signal from the timing controller 70, and sequentially output the image data, which are temporarily stored in the selected column of the output buffer 50.

The timing controller 70 may generate signals for controlling operations of the row driver 20, the ADC 40, the output buffer 50 and the column driver 60. The timing controller 70 may provide the row driver 20, the column driver 60, the ADC 40, the output buffer 50, and the column driver 60 with a clock signal required for the operations of the respective components of the image sensing device, a control signal for timing control, and address signals for selecting a row or column.

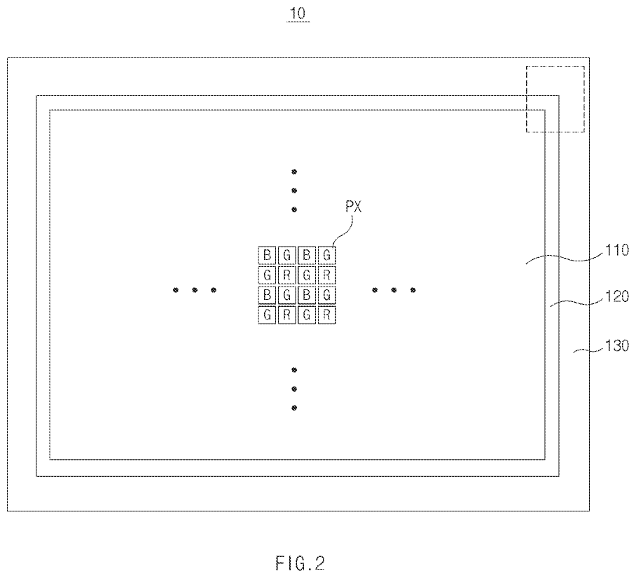

FIG. 2 is a view illustrating an example of an approximate planar structure of the light receiving region 10 shown in FIG. 1 based on some implementations of the disclosed technology.

Referring to FIG. 2, the light receiving region 10 may include a pixel region 110, a buffer region 120, and a dummy microlens region 130.

The pixel region 110 may be located in a central portion of the light receiving region 10, and may include a plurality of unit pixels (PXs) consecutively arranged in a row direction and a column direction. Each of the plurality of unit pixels may include photoelectric conversion elements that convert incident light into electrical signals. Each of the photoelectric conversion elements may include a photodiode, a phototransistor, a photogate, or a pinned photodiode.

The photoelectric conversion elements of adjacent unit pixels may be separated from each other by a device isolation layer. In some implementations, the photoelectric conversion elements are isolated on a unit pixel basis such that a photoelectric conversion element in a first unit pixel is separated from a photoelectric conversion element in a second unit pixel. The device isolation layer may include a trench isolation structure in which trenches formed in a semiconductor substrate are filled with an insulation material. In some implementations, the trenches may be formed in the semiconductor substrate by etching the semiconductor substrate. For example, the device isolation layer may include a deep trench isolation (DTI) structure.

The plurality of unit pixels (PXs) may include any one of a red color filter (R), a green color filter (G), and a blue color filter (B). The red color filters (R), the green color filters (G) and the blue color filters (B) may be arranged in an RGGB Bayer pattern. A grid structure for preventing crosstalk between adjacent color filters may be formed between the color filters R, G, and B. The grid structure may include metal (e.g., tungsten). Tungsten is the example only and other implementations are also possible.

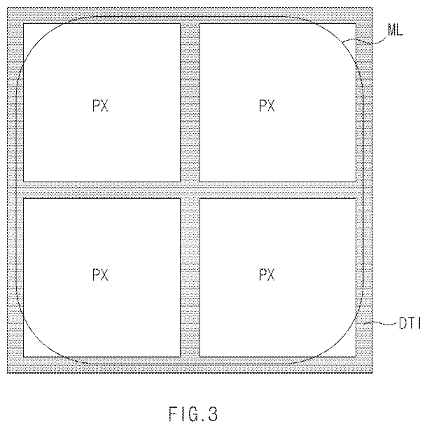

Microlenses for condensing incident light may be included over the color filters R, G, and B in the pixel region 110. For example, the microlenses may be formed in a structure in which one microlens ML covers four unit pixels PXs, as shown in FIG. 3. In the example as shown in FIG. 3, the microlens ML covers four unit pixels PXs that are arranged in a row and a column. In the example, the four unit pixels are adjacent to each other. Incident light received through one microlens may be divided into four channels by the DTI structure, so that the resultant light rays can be incident upon the photoelectric conversion elements of the corresponding unit pixels. Although FIG. 3 shows four unit pixels covered by the microlenses, other implementations are also possible. For example, one microlens may be formed for each unit pixel (PX). In this example, the microlenses may be formed to correspond to each unit pixel (PX).

A lens capping layer may be disposed over the microlenses to protect the microlenses while preventing the flare phenomenon caused by the microlenses. The lens capping layer may be formed to extend to the dummy microlens region 130 while entirely covering the pixel region 110. The lens capping layer may include a low temperature oxide (LTO) film.

The buffer region 120 may be located outside the pixel region 110. For example, the buffer region 120 may be a boundary region between the pixel region 110 and the dummy microlens region 130, and may be disposed between the pixel region 110 and the dummy microlens region 130. In the buffer region 120, color filters and microlenses are not formed over the semiconductor substrate, and a grid structure and a lens capping layer may be formed to extend from the pixel region 110.

The dummy microlens region 130 may be located outside the buffer region 120 while surrounding the pixel region 110. The dummy microlens region 130 may include three-dimensional (3D) dummy microlenses. Since the dummy microlens region 130 is disposed outside of the pixel region 110 to surround the pixel region 110, the dummy microlenses are not configured to converge the incident light. In this context, microlenses disposed in the dummy microlens region 130 are referred to as “dummy microlenses.” The dummy microlens region 130 may be configured to prevent the lens capping layer formed over the microlenses of the pixel region 110 from being peeled off. In some implementations, all or part of the dummy microlenses may be covered by the lens capping layer. For example, one lens capping layer may be formed to extend to the edge region of the dummy microlens region 130 while entirely covering the pixel region 110 and the buffer region 120.

In a region (e.g., a first dummy microlens region) of the dummy microlens region 130, which is adjacent to the buffer region 120, a grid structure may be formed to extend from the grid structure of the buffer region 120. In a region (e.g., a second dummy microlens region) of the dummy microlens region 130, which is located outside the first dummy microlens region, a light blocking layer may be formed to entirely cover the semiconductor substrate. The dummy microlenses and the lens capping layer may be disposed over the grid structure and the light blocking layer.

The dummy microlenses may include a three-dimensional (3D) anti-peel-off structure to prevent damage to the light blocking layer while preventing the lens capping layer from being peeled off. For example, the dummy microlenses may have the same convex lens shape as the microlenses of the pixel region 110 while having a larger size than the microlenses of the pixel region 110. As a result, the dummy microlens layer may enable the lens capping layer to be easily inserted into a space between the adjacent dummy microlenses, while increasing a contact area with the lens capping layer, so that the lens capping layer cannot be easily peeled off.

In some implementations, the dummy microlens region 130 may include a plurality of align patterns (hereinafter referred to as alignment patterns). The alignment patterns may be selectively formed at arbitrary positions spaced apart from one another in the semiconductor substrate. The alignment patterns may be formed to have a trench isolation structure such as a device isolation layer formed in the pixel region 110. For example, the alignment patterns may be formed to have a DTI structure in which an insulation material is buried in trenches etched to the same width and depth as the device isolation layer of the pixel region 110. These alignment patterns may be formed together when the device isolation layer of the pixel region 110 is formed.

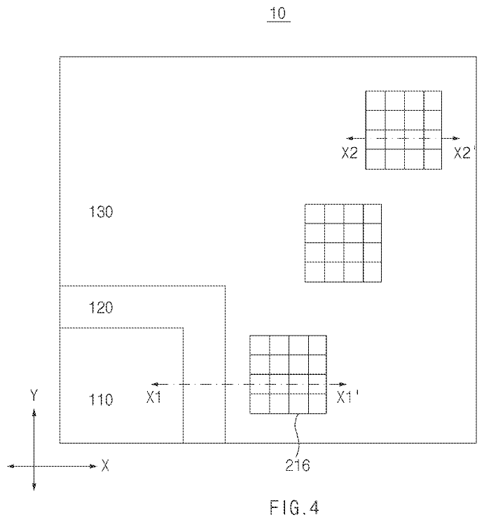

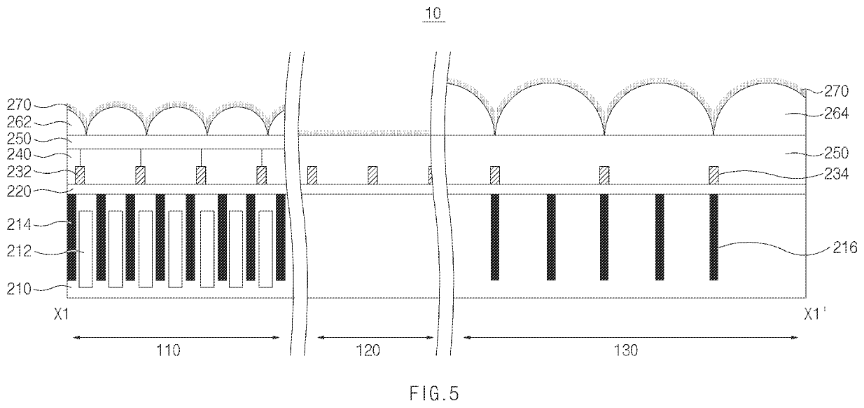

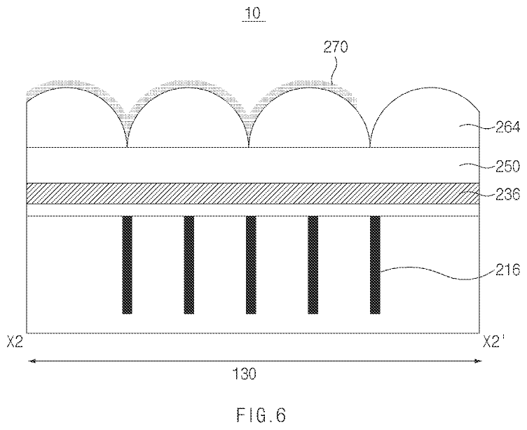

FIG. 4 is an enlarged view exemplarily illustrating a portion of the edge region denoted by a dotted line in the light receiving region 10 shown in FIG. 2 based on some implementations of the disclosed technology. FIG. 5 is a cross-sectional view illustrating an example of the light receiving region 10 taken along the line X1-X1′ shown in FIG. 4 based on some implementations of the disclosed technology. FIG. 6 is a cross-sectional view illustrating an example of the light receiving region 10 taken along the line X2-X2′ shown in FIG. 4 based on some implementations of the disclosed technology.

Referring to FIGS. 4 to 6, the light receiving region 10 may include a substrate layer 210, an anti-reflection layer 220, grid structures 232 and 234, a light blocking layer 236, a color filter layer 240, an over-coating layer 250, lens layers 262 and 264, and a lens capping layer 270.

The substrate layer 210 may include a semiconductor substrate that includes a first surface and a second surface facing the first surface. In this case, the first surface may refer to a light receiving surface upon which light is incident from the outside. The semiconductor substrate 210 may be in a monocrystalline state, and may include a silicon-containing material. For example, the semiconductor substrate 210 may include a monocrystalline silicon-containing material. The semiconductor substrate 210 may include P-type impurities implanted by ion implantation.

The semiconductor substrate 210 may include photoelectric conversion elements 212, a device isolation layer 214 for separating the photoelectric conversion elements 212 from each other, and alignment patterns 216 disposed in the dummy microlens region 130 to perform overlay measurement.

The photoelectric conversion elements 212 may convert incident light into electrical signals, and may be formed in a region defined by the device isolation layer 214. The photoelectric conversion elements 212 may be formed by implanting N-type impurities into the semiconductor substrate 210 through an ion implantation process. Each of the photoelectric conversion elements 212 may include a photodiode, a phototransistor, a photogate, or a pinned photodiode.

The device isolation layer 214 may define a region in which the photoelectric conversion elements 212 are formed in the pixel region 110, and may allow the photoelectric conversion elements 212 to be optically and electrically isolated from each other. The device isolation layer 214 may include a trench isolation structure in which an insulation material is buried in trenches etched to a predetermined depth in the semiconductor substrate 210. For example, the device isolation layer 214 may be formed in a deep trench isolation (DTI) structure.

The alignment patterns 216 may be formed in the semiconductor substrate 210 of the dummy microlens region 130 as patterns for overlay measurement. The alignment patterns 216 may be formed to have the same trench isolation structure as the device isolation layer 214. For example, the alignment patterns 216 may be formed to have a DTI structure in which an insulation material is buried in trenches etched to the same width and depth as the trenches of the device isolation layer 214. The alignment patterns 216 and the device isolation layer 214 may be formed simultaneously, but the alignment patterns 216 may be physically isolated from the device isolation layer 214. A spacing between trenches in the alignment patterns 216 may be greater than a spacing between trenches in the device isolation layer 214.

As shown in FIG. 4, the alignment patterns 216 may include a plurality of alignment patterns spaced apart from one another and disposed within the dummy microlens region 130. Although FIG. 4 illustrates an example case in which each alignment pattern 216 may be formed in a lattice shape in which five trenches extending in the X-axis direction and five trenches extending in the Y-axis directions are connected to cross each other, other implementations are also possible.

The anti-reflection layer 220 may prevent incident light from being reflected from the first surface of the semiconductor substrate 210, and may be disposed over the first surface of the semiconductor substrate 210. The anti-reflection layer 220 may have insulating properties while transmitting light therethrough, and may include a transparent insulation layer having a smaller refractive index (n1, where n1<n2) than the refractive index (n2) of the semiconductor substrate 210. The anti-reflection layer 220 may operate as a planarization layer to compensate for (or remove) a step difference that may be formed on the first surface. The grid structures 232 and 234 may be disposed over the anti-reflection layer 220.

The grid structures 232 and 234 may include a material that blocks light, for example, metal such as tungsten (W), aluminum (Al) or copper (Cu), or air. The grid structure 232 in the pixel region 110 may be formed in a boundary region between the color filter layers 240 to prevent crosstalk between adjacent color filters. The grid structure 234 may be disposed over the anti-reflection layer 220 in the dummy microlens region 130. For example, the grid structure 234 may be formed to extend from the grid structure of the buffer region 120 in the first dummy microlens region adjacent to the buffer region 120. Alternatively, the grid structure 234 may be formed to be physically isolated from the grid structure of the buffer region 120.

As shown in FIG. 5, in order to improve shading variation, the grid structure 232 disposed in the edge region of the pixel region 110 may be shifted by a predetermined distance in response to a chief ray angle (CRA) of each unit pixel. The shifting of the grid structure 232 may make the grid structure 232 not to be aligned with the device isolation layer 214. For example, the grid structure 232 may be shifted in an outward direction of the pixel region 110. For example, the grid structure 232 may be shifted outwardly by a predetermined distance in response to the CRA without being aligned with the device isolation layer 214. In some other implementations, the grid structure 232 may be shifted in a different direction other than the outward direction as long as the grid structure 232 is shifted to be not aligned with the device isolation layer 214. On the other hand, the grid structure 234 disposed in the dummy microlens region 130 may be aligned with the alignment pattern 216 without being shifted.

The light blocking layer 236 may be disposed over the anti-reflection layer 220 of the second dummy microlens region located outside the first dummy microlens region in the dummy microlens region 130. The light blocking layer 236 may entirely cover the second dummy microlens region to prevent incident light from being incident upon the semiconductor substrate 210 of the second dummy microlens region.

The color filter layer 240 may be formed in a region defined by the grid structure 232 on the anti-reflection layer 220. The color filter layer 240 may include color filters that selectively transmit visible light of a specific color. For example, the color filter layer 240 may include red color filters (R), green color filters (G), and blue color filters (B) arranged in a Bayer pattern. Each of the color filters may be formed to correspond to each unit pixel in the pixel region 110, and may not be formed in the buffer region 120 and the dummy microlens region 130.

The over-coating layer 250 may be formed over the color filter layer 240 to compensate for (remove) a step difference caused by the color filter layer 240. The over-coating layer 250 may be formed to cover the anti-reflection layer 220, the grid structure 234, and the light blocking layer 236 in the buffer region 120 and the dummy microlens region 130. The over-coating layer layer 250 may include the same material as the lens layer 262.

The lens layers 262 and 264 may be formed over the over-coating layer 250. The lens layers 262 and 264 may include microlenses 262 disposed in the pixel region 110 and dummy microlenses 264 disposed in the dummy microlens region 130. The lens layers 262 and 264 may not be formed in the buffer region 120.

The microlenses 262 may converge incident light onto the photoelectric conversion elements 212 of the corresponding unit pixels. As shown in FIG. 3, the microlenses 262 may be formed to have a structure in which one microlens 262 covers four adjacent unit pixels. The dummy microlenses 264 may include a three-dimensional (3D) anti-peel-off structure to prevent damage to the light blocking layer while preventing the lens capping layer 270 from being peeled off. For example, the dummy microlenses 264 may have the same convex lens shape as the microlenses 262 of the pixel region 110, and may have a larger size than the microlenses 262 of the pixel region 110. As a result, the dummy microlens 264 may enable the lens capping layer 270 to be easily inserted into a space between the adjacent dummy microlenses 264 while increasing a contact area with the lens capping layer.

In order to improve shading variation, the microlenses 262 may be shifted by a predetermined distance in response to a chief ray angle (CRA) of each unit pixel. The shifting of the microlenses 262 may make the microlenses 262 not to be aligned with the device isolation layer 214. For example, the microlenses 262 may be shifted in an outward direction of the pixel region 110. For example, the microlenses 262 may be shifted outwardly by a predetermined distance in response to the CRA without being aligned with the device isolation layer 214 and the grid structure 232. In some other implementations, the microlenses 262 may be shifted in a different direction other than the outward direction as long as the microlenses 262 is shifted to be not aligned with the device isolation layer 214. On the other hand, the dummy microlenses 264 may be aligned with the grid structure 234 and the alignment pattern 216 without being shifted.

The lens capping layer 270 may protect the microlenses 262, and may prevent the flare phenomenon caused by the microlenses 262. The lens capping layer 270 may be formed over the lens layers 262 and 264 and the over-coating layer 250. For example, whereas the lens capping layer 270 may be formed over the lens layers 262 and 264 in the pixel region 110 and the dummy microlens region 130, the lens capping layer 270 may be formed over the over-coating layer in the buffer region 120 in which the lens layers 262 and 264 are not formed. The lens capping layer 270 may be formed as a single layer extending from the pixel region 110 to the dummy microlens region 130.

The lens capping layer 270 may be formed to entirely cover the dummy microlens region 130 or to cover a portion of the dummy microlens region 130. Since the dummy microlenses 264 are not lenses for generating pixel signals but lenses formed to prevent the lens capping layer 270 from being peeled off, the dummy microlenses need not cover all of the dummy microlenses 264. Accordingly, the dummy microlenses 264 in the edge region of the dummy microlens region 130 may not be covered by the lens capping layer 270.

In the embodiment of FIG. 5, the grid structure 232 may be disposed to correspond to the boundary region between adjacent microlenses 262, and the grid structure 234 may be aligned with the boundary region between adjacent dummy microlenses 264. In the example of FIG. 5, the grid structure 232 may not be aligned with the boundary region between adjacent dummy microlenses 264.

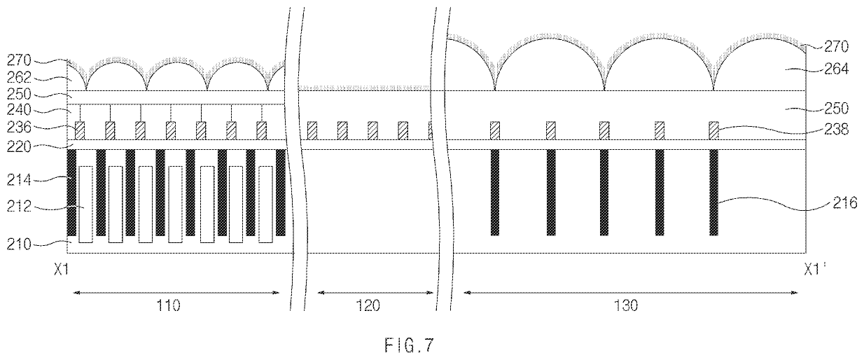

However, as shown in FIG. 7, the grid structure 236 of the pixel region 110 may be disposed to correspond not only to the boundary region between the microlenses 262 but also to the center portion of each microlens 262. The grid structure 238 of the dummy microlens region 130 may be aligned with the center portion of the dummy microlenses 264 as well as the boundary region between the dummy microlenses 264.

In addition, although the embodiments of FIGS. 5 and 6 have disclosed only components formed on the first surface of the semiconductor substrate 210 for convenience of description, other implementations are also possible, and elements (e.g., pixel transistors) for reading out photocharges generated by the photoelectric conversion elements 212 and then outputting pixel signals can also be formed over the second surface of the semiconductor substrate.

As is apparent from the above description, the image sensing device based on some implementations of the disclosed technology can easily perform overlay analysis using the deep trench 5 isolation (DTI) structure.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a pixel region provided in a first portion of a semiconductor substrate such that photoelectric conversion elements for converting incident light into an electrical signal are disposed in the first portion of the semiconductor substrate;
a dummy region located outside the pixel region to surround the pixel region and provided in a second portion of the semiconductor substrate without including a photoelectric conversion element;
first microlenses disposed over the first portion of the semiconductor substrate and in the pixel region, the first microlenses configured to converge the incident light onto corresponding photoelectric conversion elements;
second microlenses disposed over the second portion of the semiconductor substrate and in the dummy region, the second microlenses isolated from the first microlenses; and
at least one alignment pattern disposed in the second portion of the semiconductor substrate so as to be aligned with the second microlenses.

2. The image sensing device according to claim 1, further comprising:
a lens capping layer extending to cover at least a portion of the second microlenses and covering all of the first microlenses.

3. The image sensing device according to claim 1, wherein the at least one alignment pattern includes:
a trench isolation structure in which an insulation material is buried in a trench formed in the second portion of the semiconductor substrate.

4. The image sensing device according to claim 3, wherein the at least one alignment pattern includes:
a grid structure in which a plurality of trenches extending in a first direction and a plurality of trenches extending in a second direction crossing the first direction are arranged to cross each other.

5. The image sensing device according to claim 1, wherein the pixel region includes:
a device isolation layer including a trench isolation structure in which an insulation material is buried in trenches formed in the first portion of the semiconductor substrate, the trench isolation structure configured to isolate a photoelectric conversion element in a first unit pixel from a photoelectric conversion element in a second unit pixel adjacent to the first unit pixel.

6. The image sensing device according to claim 5, wherein the at least one alignment pattern includes:
a trench isolation structure in which an insulation material is buried in trenches having a width and a depth that are same as a width and a depth of the trenches of the device isolation layer in the dummy region.

7. The image sensing device according to claim 6, wherein:
a spacing between trenches of the at least one alignment pattern is greater than a spacing between the trenches of the device isolation layer.

8. The image sensing device according to claim 1, wherein:
each of the first microlenses is configured to cover a plurality of unit pixels adjacent to each other.

9. The image sensing device according to claim 8, wherein:
the second microlenses have a size different from a size of the first microlenses.

10. The image sensing device according to claim 1, wherein the semiconductor substrate further includes:
a buffer region disposed between the pixel region and the dummy region,
wherein the buffer region is free of microlenses.

11. The image sensing device according to claim 1, wherein:
the dummy region includes a first dummy region adjacent to the pixel region and a second dummy region located outside the first dummy region; and
wherein the first dummy region includes a grid structure disposed over the second portion of the semiconductor substrate so as to be aligned with the alignment pattern.

12. The image sensing device according to claim 11, wherein the second dummy region includes:
a light blocking layer configured to prevent light from being incident upon a corresponding portion of the semiconductor substrate to the second dummy region.

13. The image sensing device according to claim 1, wherein the pixel region includes:
a grid structure disposed between the color filters to prevent crosstalk between adjacent color filters,
wherein the grid structure includes:
first grid structures aligned with a boundary region between the first microlenses; and
second grid structures disposed between the first grid structures without being aligned with the boundary region between the first microlenses.

14. An image sensing device comprising:
a first region configured to include photoelectric conversion elements for converting incident light into electrical signals and first microlenses for converging incident light onto the photoelectric conversion elements; and
a second region located outside the first region and configured to include second microlenses having a size different from a size of the first microlenses,
wherein the second region includes at least one alignment pattern disposed in a semiconductor substrate so as to be aligned with a portion of the second microlenses.

15. The image sensing device according to claim 14, further comprising:
a lens capping layer extending to cover at least a portion of the second microlenses and covering all of the first microlenses.

16. The image sensing device according to claim 14, wherein:
each of the first microlenses is formed to have a size that covers adjacent photoelectric conversion elements.

17. The image sensing device according to claim 14, wherein:
the second microlenses are spaced apart from the first microlenses by a predetermined distance.

18. The image sensing device according to claim 14, wherein:
each of the second microlenses has a size greater than that of each of the first microlenses.

19. The image sensing device according to claim 14, wherein the at least one alignment pattern includes:
a trench isolation structure in which an insulation material is buried in a trench formed in the semiconductor substrate.

20. The image sensing device according to claim 19, wherein the at least one alignment pattern includes:
a grid structure in which a plurality of trenches extending in a first direction and a plurality of trenches extending in a second direction crossing the first direction are arranged to cross each other.
